(19) United States
(12) Patent Application Publication
(10) Pub. No.: US 2026/0018857 A1
(43) Pub. Date: Jan. 15, 2026

(54) SEMICONDUCTOR LIGHT ELEMENT AND METHOD OF MANUFACTURING THE SAME

(71) Applicant: SUMITOMO ELECTRIC INDUSTRIES, LTD., Osaka-shi (JP)

(72) Inventor: Hidenari FUJIKATA, Osaka-shi (JP)

(73) Assignee: SUMITOMO ELECTRIC INDUSTRIES, LTD., Osaka-shi (JP)

(21) Appl. No.: 19/259,852

(22) Filed: Jul. 3, 2025

(30) Foreign Application Priority Data
Jul. 9, 2024 (JP) 2024-110468

(51) Int. Cl. H01S 5/026; H01S 5/024

(52) U.S. Cl. CPC H01S 5/026; H01S 5/02469

(57) ABSTRACT

A method of manufacturing a semiconductor light element is a method of manufacturing a semiconductor light element including a substrate having a first layer, a second layer, and a third layer stacked in this order, and a semiconductor element having an optical gain. The third layer is provided with a waveguide. The method includes bonding the semiconductor element to the waveguide in the third layer, providing an insulating film covering the substrate and the semiconductor element bonded to the waveguide, forming an emitting end face facing a tip end of the waveguide, and forming a heat dissipation structure provided at a position spaced apart from the waveguide. The forming the emitting end face includes etching a portion of the second layer and the insulating film, the portion facing the tip end of the waveguide.

### CROSS REFERENCE TO RELATED APPLICATIONS

This application claims priority based on Japanese Patent Application No. 2024-110468 filed on Jul. 9, 2024, and the entire contents of the Japanese patent application are incorporated herein by reference.

### TECHNICAL FIELD

The present disclosure relates to a semiconductor light element and a method of manufacturing the same.

### BACKGROUND

A technique in which a semiconductor element formed of a compound semiconductor and having an optical gain is bonded to a substrate such as a silicon on insulator (SOI) substrate (silicon photonics) on which a waveguide is formed is known (for example, non-patent literature 1: Martin Schnarrenberger et al. “Facet Preparation of SOI Waveguides by Etching and Cleaving Compared to Dicing and Polishing”, First IEEE International Conference on Group IV Photonics, 29 Sep. 2004-1 Oct. 2004). Light generated in the semiconductor element propagates through the waveguide of the substrate and is emitted.

### SUMMARY

A method of manufacturing a semiconductor light element according to the present disclosure is a method of manufacturing a semiconductor light element including a substrate having a first layer, a second layer, and a third layer stacked in this order, and a semiconductor element having an optical gain. The third layer is provided with a waveguide. The method includes bonding the semiconductor element to the waveguide in the third layer; providing an insulating film covering the substrate and the semiconductor element bonded to the waveguide; forming an emitting end face facing a tip end of the waveguide; and forming a heat dissipation structure provided at a position spaced apart from the waveguide. The forming the emitting end face includes etching a portion of the second layer and the insulating film, the portion facing the tip end of the waveguide. The forming the heat dissipation structure includes etching a portion of the second layer and the insulating film, the portion being spaced apart from the waveguide, and providing a metal layer extending between the portion etched in the etching and the semiconductor element. The etching in the forming the emitting end face and the etching in the forming the heat dissipation structure are performed simultaneously.

### BRIEF DESCRIPTION OF THE DRAWINGS

FIG. 1 is a perspective view illustrating a semiconductor light element according to an embodiment.

FIG. 2A is a cross-sectional view illustrating a semiconductor light element.

FIG. 2B is a cross-sectional view illustrating a semiconductor light element.

FIG. 3 is a diagram illustrating a coupling efficiency.

FIG. 4 is a flow chart illustrating a method of manufacturing a semiconductor light element.

FIG. 5 is a flow chart illustrating a method of manufacturing a semiconductor light element.

FIG. 6 is a cross-sectional view illustrating a method of manufacturing a semiconductor light element.

FIG. 7A is a plan view illustrating a method of manufacturing a semiconductor light element.

FIG. 7B is a cross-sectional view illustrating a method of manufacturing a semiconductor light element.

FIG. 8A is a plan view illustrating a method of manufacturing a semiconductor light element.

FIG. 8B is a cross-sectional view illustrating a method of manufacturing a semiconductor light element.

FIG. 9A is a plan view illustrating a method of manufacturing a semiconductor light element.

FIG. 9B is a cross-sectional view illustrating a method of manufacturing a semiconductor light element.

FIG. 10A is a plan view illustrating a method of manufacturing a semiconductor light element.

FIG. 10B is a cross-sectional view illustrating a method of manufacturing a semiconductor light element.

FIG. 11A is a plan view illustrating a method of manufacturing a semiconductor light element.

FIG. 11B is a cross-sectional view illustrating a method of manufacturing a semiconductor light element.

FIG. 12A is a plan view illustrating a method of manufacturing a semiconductor light element.

FIG. 12B is a cross-sectional view illustrating a method of manufacturing a semiconductor light element.

FIG. 13A is a plan view illustrating a method of manufacturing a semiconductor light element.

FIG. 13B is a cross-sectional view illustrating a method of manufacturing a semiconductor light element.

FIG. 14A is a plan view illustrating a method of manufacturing a semiconductor light element.

FIG. 14B is a cross-sectional view illustrating a method of manufacturing a semiconductor light element.

FIG. 15A is a plan view illustrating a method of manufacturing a semiconductor light element.

FIG. 15B is a cross-sectional view illustrating a method of manufacturing a semiconductor light element.

FIG. 16A is a plan view illustrating a method of manufacturing a semiconductor light element.

FIG. 16B is a cross-sectional view illustrating a method of manufacturing a semiconductor light element.

FIG. 17A is a plan view illustrating a method of manufacturing a semiconductor light element.

FIG. 17B is a cross-sectional view illustrating a method of manufacturing a semiconductor light element.

FIG. 18A is a plan view illustrating a method of manufacturing a semiconductor light element.

FIG. 18B is a cross-sectional view illustrating a method of manufacturing a semiconductor light element.

FIG. 19 is a flow chart illustrating manufacturing steps in a comparative example.

### DETAILED DESCRIPTION

A substrate is provided with an emitting end face for emitting light and a heat dissipation structure for releasing heat generated during operation.

When the emitting end face and the heat dissipation structure are formed in separate steps, the steps are complicated and lead time is long.

Thus, it is an object of the present disclosure to provide a semiconductor light element and a method of manufacturing the same, which can shorten the lead time.

### DESCRIPTION OF EMBODIMENTS OF PRESENT DISCLOSURE

First, the contents of embodiments of the present disclosure will be listed and explained.
(1) A method of manufacturing a semiconductor light element according to an aspect of the present disclosure is a method of manufacturing a semiconductor light element including a substrate having a first layer, a second layer, and a third layer stacked in this order, and a semiconductor element having an optical gain. The third layer is provided with a waveguide. The method includes bonding the semiconductor element to the waveguide in the third layer; providing an insulating film covering the substrate and the semiconductor element bonded to the waveguide; forming an emitting end face facing a tip end of the waveguide; and forming a heat dissipation structure provided at a position spaced apart from the waveguide. The forming the emitting end face includes etching a portion of the second layer and the insulating film, the portion facing the tip end of the waveguide. The forming the heat dissipation structure includes etching a portion of the second layer and the insulating film, the portion being spaced apart from the waveguide, and providing a metal layer extending between the portion etched in the etching and the semiconductor element. The etching in the forming the emitting end face and the etching in the forming the heat dissipation structure are performed simultaneously. Since the etching is performed simultaneously, the lead time can be shortened.
(2) In the above (1), the etching in the forming the emitting end face and the etching in the forming the heat dissipation structure may include performing a dry etching using a gas containing carbon. The emitting end face can be a flat surface.
(3) In any one of the above (1) and (2), the emitting end face may have an angle of 80 degrees to 90 degrees with respect to an extending direction of the waveguide. A coupling efficiency is increased.
(4) In any one of the above (1) to (3), the emitting end face may be formed of end faces of the insulating film and the second layer. The insulating film and the second layer are positioned between the waveguide and air. The refractive index gradually changes between the waveguide and air. The coupling efficiency is increased.
(5) In any one of the above (1) to (4), the second layer and the insulating film may be formed of silicon oxide. The first layer and the third layer may be formed of silicon. Since the second layer and the insulating film are formed of the same material, etching rate and the like can be easily controlled. Since a silicon waveguide is surrounded by the second layer and the insulating film, light is distributed in the waveguide, and loss is reduced.
(6) In any one of the above (1) to (5), the etching in the forming the emitting end face and the etching in the forming the heat dissipation structure may include etching the second layer and the insulating film until the first layer is exposed. Since the emitting end face and the heat dissipation structure are etched simultaneously to the same depth, the manufacturing is easy.
(7) In any one of the above (1) to (6), the method of manufacturing a semiconductor light element may further include etching the first layer exposed at a position facing the tip end of the waveguide after the forming of the emitting end face. The emitted light is less likely to hit the first layer.
(8) In any one of the above (1) to (7), the method of manufacturing a semiconductor light element may further include dicing the first layer after the forming the heat dissipation structure and the forming the emitting end face. The dicing may include dicing a portion of the first layer outside the emitting end face. The emitted light is less likely to hit the first layer.
(9) In any one of the above (1) to (8), the metal layer may be an electrode and may be electrically connected to the semiconductor element. Heat generated in the semiconductor element is dissipated through the electrode.
(10) A semiconductor light element includes a substrate including a first layer, a second layer, and a third layer that are stacked in this order, a semiconductor element having an optical gain, and a heat dissipation structure configured to dissipate heat from the semiconductor element. The third layer is provided with a waveguide. The semiconductor element is bonded to the waveguide in the third layer. The substrate has an emitting end face to emit light propagating through the waveguide. The first layer has a protruding portion facing toward an extending direction of the waveguide at the emitting end face. The lead time can be shortened. Light is unlikely to hit the first layer of the substrate.

### DETAILS OF EMBODIMENTS OF PRESENT DISCLOSURE

Specific examples of a semiconductor light element and a method of manufacturing the same according to embodiments of the present disclosure will be described below with reference to the drawings. The present disclosure is not limited to these examples, but is defined by the scope of the claims, and is intended to include all modifications within the meaning and scope equivalent to the scope of the claims.

### (Semiconductor Light Element)

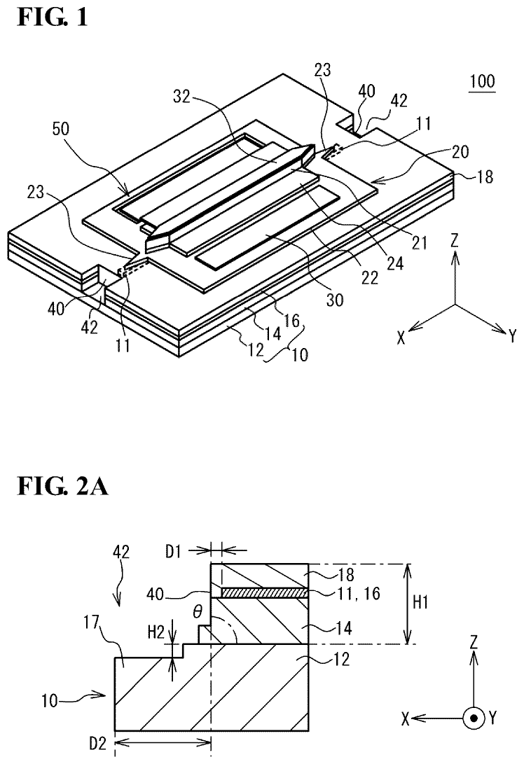

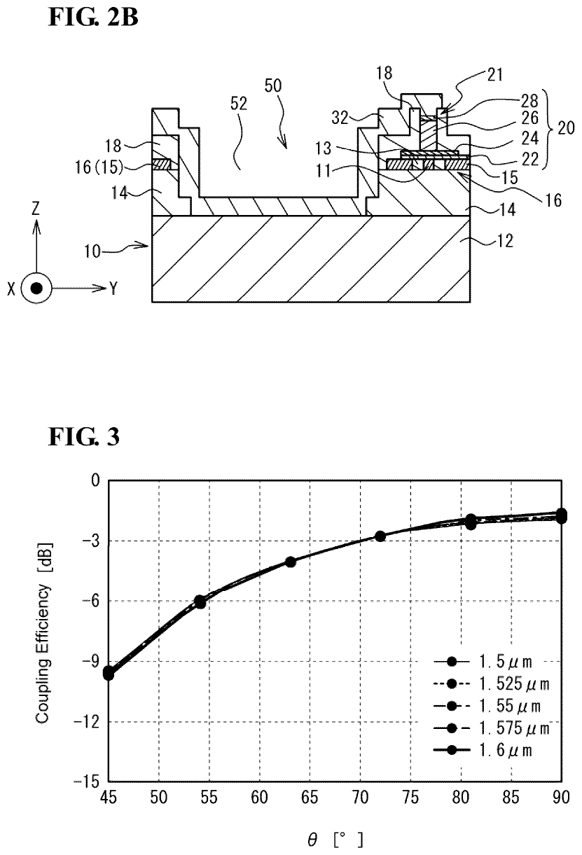

FIG. 1 is a perspective view illustrating a semiconductor light element 100 according to an embodiment. As shown in FIG. 1, the semiconductor light element 100 is a hybrid laser element, and includes a substrate 10 and a semiconductor element 20. The semiconductor light element 100 has an emitting end face 40 to emit light and a heat dissipation structure 50 to dissipate heat. FIGS. 2A and 2B are cross-sectional views illustrating the semiconductor light element 100. FIG. 2A illustrates a cross-section including the emitting end face 40. FIG. 2B illustrates a cross-section including the heat dissipation structure 50 and the semiconductor element 20. The emitting end face 40 and the heat dissipation structure 50 will be described later. An X-axis direction is a direction in which light propagates. A Y-axis direction is a width direction of the semiconductor light element 100. A Z-axis direction is a normal direction of the upper surface of the substrate 10. The X-axis direction, the Y-axis direction, and the Z-axis direction are orthogonal to each other.

As shown in FIGS. 1 to 2B, the substrate 10 is a silicon on insulator (SOI) substrate, and includes a substrate 12 (first layer), a box layer 14 (second layer), and a silicon layer 16 (third layer). The substrate 12, the box layer 14, and the silicon layer 16 are stacked in this order in the Z-axis direction. The substrate 12 is formed of, for example, silicon (Si). The box layer 14 is formed of, for example, silicon oxide (SiO₂). The thickness of the box layer 14 is, for example, 3 μm. The thickness of the silicon layer 16 is, for example, 220 nm.

As shown in FIG. 2B, the silicon layer 16 has a waveguide 11 and a terrace 15. The waveguide 11 is parallel to the X-axis direction. The terraces 15 are plate-shaped and are located on both sides of the waveguide 11 in the Y-axis direction. The upper surface of the waveguide 11 and the upper surface of the terrace 15 are located at the same height in the Z-axis direction. A recessed portion 13 is provided between the waveguide 11 and the terrace 15. The recessed portion 13 is recessed from the upper surface of the waveguide 11 in the Z-axis direction. The recessed portion 13 may penetrate the silicon layer 16 or may extend to the middle of the silicon layer 16.

The semiconductor element 20 is a light emitting element, has an optical gain, and is formed of a III-V compound semiconductor. As shown in FIGS. 1 and 2B, the semiconductor element 20 is bonded to the upper surface of the silicon layer 16 and is positioned on the waveguide 11.

As shown in FIG. 2B, the semiconductor element 20 includes a cladding layer 22, an active layer 24, a cladding layer 26, and a contact layer 28. The cladding layer 22 is in contact with the silicon layer 16. On the side opposite to the silicon layer 16 with respect to the cladding layer 22, the active layer 24, the cladding layer 26 and the contact layer 28 are stacked in this order. The semiconductor element 20 may include a semiconductor layer other than the above semiconductor layer.

The cladding layer 22 is formed of, for example, n-type indium phosphide (n-InP). The active layer 24 has, for example, a multi quantum well (MQW). The active layer 24 includes a plurality of well layers and barrier layers. The well layers and the barrier layers are alternately stacked. The well layer and the barrier layer are formed of, for example, non-doped gallium indium arsenide phosphide (i-GaInAsP). The cladding layer 26 is formed of, for example, p-type InP (p-InP). The contact layer 28 is formed of, for example, (p+)-type gallium indium arsenide ((p+)-GaInAs). A guide layer may be provided between the active layer 24 and the cladding layer 22 and between the active layer 24 and the cladding layer 26 to form a separate confinement heterostructure (SCH).

As shown in FIG. 1, the semiconductor element 20 includes a mesa 21 and a tapered portion 23. The mesa 21 is located on the waveguide 11 and extends in parallel to the X-axis direction. Both ends of the mesa 21 in the X-axis direction have a tapered shape. The cladding layer 22 and the active layer 24 are plate-shaped and extend from underneath the mesa 21 outward beyond the mesa 21. The cladding layer 22 extends outward beyond the active layer 24. The tapered portion 23 is provided in the cladding layer 22 and extends in the X-axis direction. The tapered end of the mesa 21 and the tapered portion 23 taper away from the semiconductor element 20. As shown in FIG. 2B, the mesa 21 includes the cladding layer 26 and the contact layer 28 and protrudes from the active layer 24 in the Z-axis direction.

As shown in FIG. 2B, the upper surface of the substrate 10 and the semiconductor element 20 are covered with an insulating film 18. The insulating film 18 is formed of an insulating material such as SiO₂, and functions as a cladding layer. The thickness of the insulating film 18 is, for example, 1.2 μm. The insulating film 18 is filled in the recessed portion 13 of the substrate 10. The insulating film 18 has an opening on the cladding layer 22 at a position spaced apart from the mesa 21, and also has an opening on the mesa 21.

As shown in FIG. 1, the semiconductor light element 100 includes an electrode 30 and an electrode 32. The electrode 30 is provided on the cladding layer 22 at a position spaced from the mesa 21. The electrode 30 is electrically connected to the cladding layer 22 through the opening of the insulating film 18. The electrode 32 (metal layer) is provided on the mesa 21 and is electrically connected to the contact layer 28 through the opening of the insulating film 18. The electrode 30 and the electrode 32 are formed of metal.

A voltage is applied to the semiconductor element 20 using the electrode 30 and the electrode 32. The active layer 24 of the semiconductor element 20 has an optical gain and generates light in response to the injection of carriers. The semiconductor element 20 and the substrate 10 are optically coupled by evanescent optical coupling. A refractive index gradually changes at the tapered end of the mesa 21 and the tapered portion 23. The light generated in the semiconductor element 20 is transferred to the waveguide 11 at the end of the mesa 21 and the tapered portion 23. The light propagates through the waveguide 11 and is emitted from the emitting end face 40 to the outside of the semiconductor light element 100. The semiconductor light element 100 has two emitting end faces 40. The two emitting end faces 40 are provided at positions facing the tapered portions 23 at both ends of the semiconductor element 20.

(Emitting End Face) As shown in FIG. 2A, the substrate 10 is provided with a recessed portion 42, and the emitting end face 40 is provided in the recessed portion 42. The emitting end face 40 is an end face of the box layer 14 and the insulating film 18, is perpendicular to an X-axis, and faces the tip end of the waveguide 11. A distance D1 from the tip end of the waveguide 11 to the emitting end face 40 is, for example, 3 μm. The insulating film 18 and the box layer 14 formed of SiO₂ are provided between the tip end of the waveguide 11 and the emitting end face 40. The wavelength of the emitted light is, for example, 1.55 μm. At this wavelength, the refractive index of the box layer 14 and the insulating film 18 is lower than the refractive index of the silicon layer 16 and higher than the refractive index of air. Since the refractive index gradually changes between the waveguide 11 and air, the loss of light is low.

The mode of the light spreads in a range of, for example, about 2.5 μm. In the vicinity of the emitting end face 40, a height H1 from the upper surface of the substrate 12 to the upper surface of the insulating film 18 is, for example, 3.2 μm. The mode can be confined near the waveguide 11.

The substrate 12 has a protruding portion 17. The protruding portion 17 protrudes in the X-axis direction from the emitting end face 40. A distance D2 between the tip end of the protruding portion 17 and the emitting end face 40 is, for example, 5 μm. A depth H2 from the surface of the substrate 12 in contact with the box layer 14 to the upper surface of the protruding portion 17 is, for example, 1 μm. The light emitted from the emitting end face 40 is less likely to hit the protruding portion 17 of the substrate 12, and the loss is reduced.

FIG. 3 is a diagram illustrating a coupling efficiency. A horizontal axis represents an angle θ between the emitting end face 40 and the upper surface of the substrate 12. In FIG. 3, the angle θ is set to 45 degrees to 90 degrees. A vertical axis represents the calculation result of the coupling efficiency. The wavelength of light is changed from 1.5 μm to 1.6 μm in increments of 0.25 μm. A thin solid line represents an example of a wavelength of 1.5 μm. A dotted line represents an example of a wavelength of 1.525 μm. A dashed line represents an example of a wavelength of 1.55 μm. A dash-dot line represents an example of a wavelength of 1.575 μm. A thick solid line represents an example of a wavelength of 1.6 μm. At any wavelength, the coupling efficiency increases as the angle θ approaches 90 degrees. In order to make the coupling efficiency −2 dB or more, the angle θ sets to 80 degrees to 90 degrees.

In order to increase the coupling efficiency, the emitting end face 40 is made closer to the vertical as described above. Further, the emitting end face 40 is formed as a flat surface. However, polishing to form the flat emitting end face 40 results in a long lead time. In order to form one emitting end face, about 100 μm of the wafer is polished. The number of the semiconductor light elements 100 that can be obtained from the wafer may be reduced.

### (Heat Dissipation Structure)

When the semiconductor element 20 is operated, heat is generated. Heat is released from the semiconductor element 20 through the heat dissipation structure 50. The heat dissipation structure 50 includes a recessed portion 52 and the electrode 32. As shown in FIG. 2B, the recessed portion 52 extends to the substrate 12 in the Z-axis direction and is spaced apart from the semiconductor element 20 in the Y-axis direction. The insulating film 18, the silicon layer 16, and the box layer 14 are not provided in the recessed portion 52. The box layer 14, the terrace 15 of the silicon layer 16, and the insulating film 18 are provided at a position of the recessed portion 52 opposite to the semiconductor element 20. The electrode 32 extends between the mesa 21 of the semiconductor element 20 and the recessed portion 52, and extends from the inside of the recessed portion 52 to the surface of the insulating film 18 opposite to the semiconductor element 20. The electrode 32 is in contact with the mesa 21 of the semiconductor element 20 and is in contact with the surface of the substrate 12 in the recessed portion 52. Heat generated in the semiconductor element 20 is transferred to the substrate 12 through the electrode 32 and is dissipated from the substrate 12.

If the step of forming the emitting end face 40 and the step of forming the heat dissipation structure 50 are performed separately, the steps become complicated and the lead time becomes long. As described above, the lead time of polishing is also long. In the first embodiment, the emitting end face 40 and the heat dissipation structure 50 are formed by a simple step without polishing.

### (Manufacturing Method)

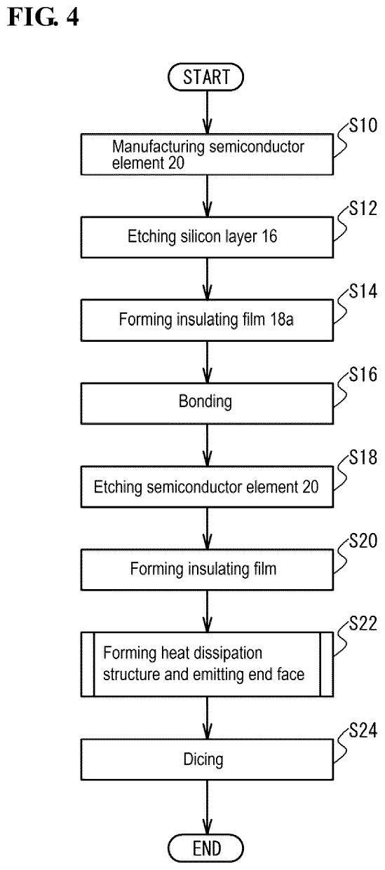

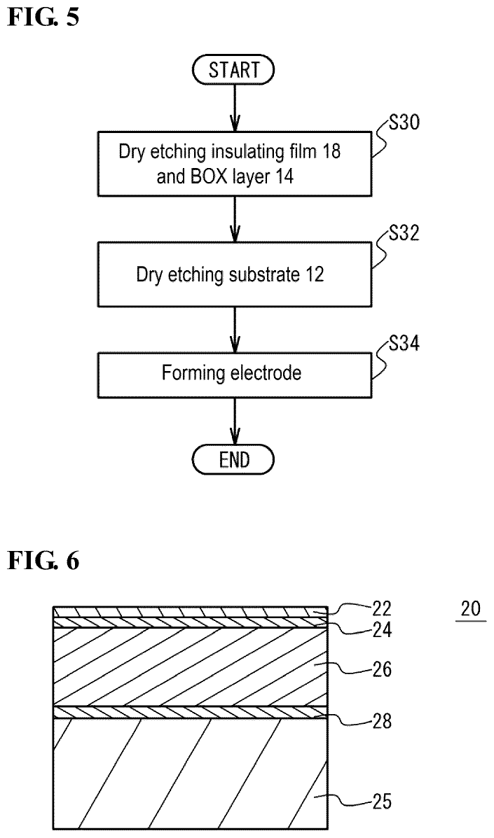

FIGS. 4 and 5 are flow charts illustrating a method of manufacturing the semiconductor light element 100. FIG. 5 illustrates the steps of forming the emitting end face 40 and the heat dissipation structure 50 of the manufacturing method.

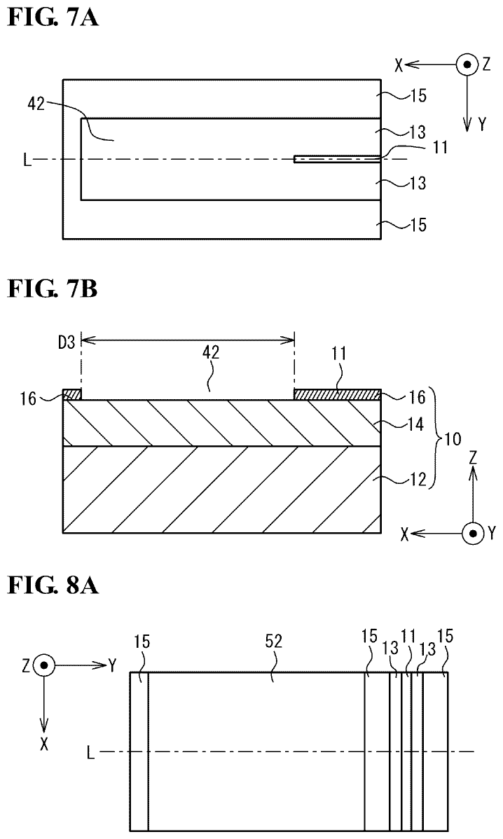

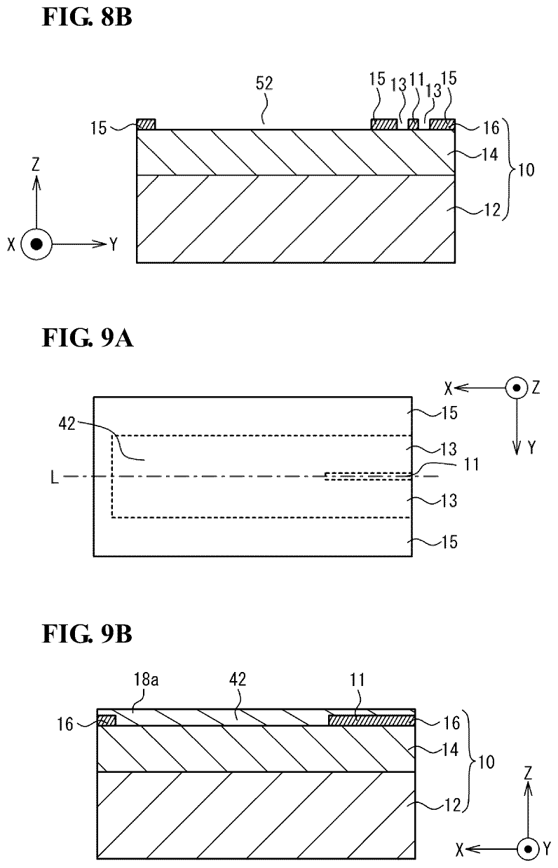

FIG. 6 is a cross-sectional view illustrating a method of manufacturing the semiconductor light element 100. FIGS. 7A, 8A, 9A, 10A, 11A, 12A, 13A, 14A, 15A, 16A, 17A, and 18A are plan views illustrating a method of manufacturing the semiconductor light element 100. FIGS. 7B, 8B, 9B, 10B, 11B, 12B, 13B, 14B, 15B, 16B, 17B and 18B are cross-sectional views illustrating the method of manufacturing the semiconductor light element 100, and illustrate the cross-section along a line L of the corresponding plan views. FIGS. 7A and 7B, FIGS. 9A and 9B, FIGS. 11A and 11B, FIGS. 13A and 13B, FIGS. 15A and 15B, and FIGS. 18A and 18B illustrate the portion where the emitting end face 40 is formed. FIGS. 8A and 8B, FIGS. 10A and 10B, FIGS. 12A and 12B, FIGS. 14A and 14B, FIGS. 16A and 16B, and FIGS. 17A and 17B illustrate the portion of the heat dissipation structure 50.

A step S10 and a step S12 in FIG. 4 may be performed in parallel. Here, the step S10 will be described first. As shown in FIG. 6, the contact layer 28, the cladding layer 26, the active layer 24, and the cladding layer 22 are epitaxially grown in this order on an InP substrate 25 by, for example, metal organic chemical vapor deposition (MOCVD) (step S10 in FIG. 4). The substrate 25 is diced to form the rectangular semiconductor element 20. In this step, the mesa 21, the tapered portion 23, and the like are not provided in the semiconductor element 20.

The steps from the step S12 to a step S24 in FIG. 4 are performed on the wafer of the substrate 10. As shown in FIGS. 7A to 8B, the silicon layer 16 of the substrate 10 is etched (step S12). The recessed portion 13 is formed in the silicon layer 16. The waveguide 11 is formed at a position sandwiched by the recessed portions 13. The terrace 15 is formed outside the recessed portion 13. As shown in FIGS. 7A and 7B, the recessed portion 42 is formed at a position facing the tip end of the waveguide 11 by etching. The recessed portion 42 penetrates the silicon layer 16, and the box layer 14 is exposed. A length D3 of the recessed portion 42 in the X-axis direction is, for example, 30 μm. As shown in FIGS. 8A and 8B, the recessed portion 52 is formed at a position spaced apart from the waveguide 11 in the Y-axis direction by etching. The recessed portion 52 penetrates the silicon layer 16, and the box layer 14 is exposed.

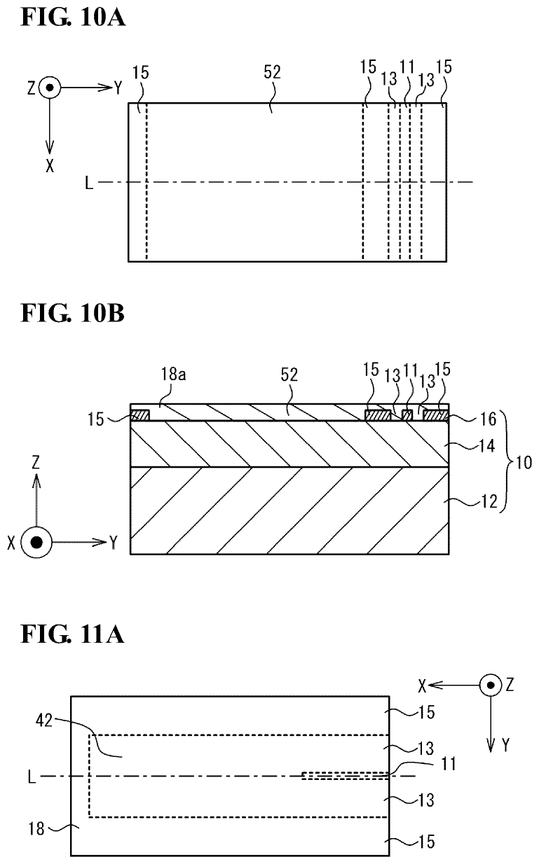

As shown in FIGS. 9A to 10B, an insulating film 18a is formed by, for example, a plasma enhanced CVD (step S14). The insulating film 18a covers the upper surface of the silicon layer 16 and is embedded in the recessed portion 42 and the recessed portion 52.

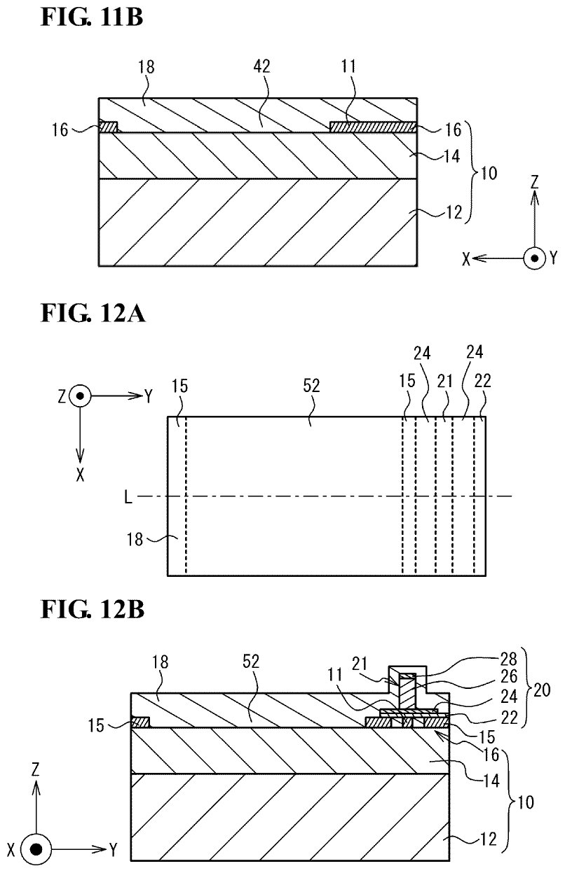

As shown in FIGS. 12A and 12B, the insulating film 18a is removed from the waveguide 11, and the semiconductor element 20 is bonded onto the waveguide 11 (step S16 in FIG. 4). The bonding method may be hydrophilization bonding or plasma activation bonding. After the bonding, etching is performed to remove the substrate 25 from the semiconductor element 20. Further, etching is performed to form the mesa 21 and the tapered portion 23 in the semiconductor element 20 (step S18). The active layer 24 and the cladding layer 22 are formed in a plate shape. As shown in FIGS. 11A to 12B, an insulating film is formed on the insulating film 18a and the semiconductor element 20 (step S20). The added insulating film and the insulating film 18a form the insulating film 18.

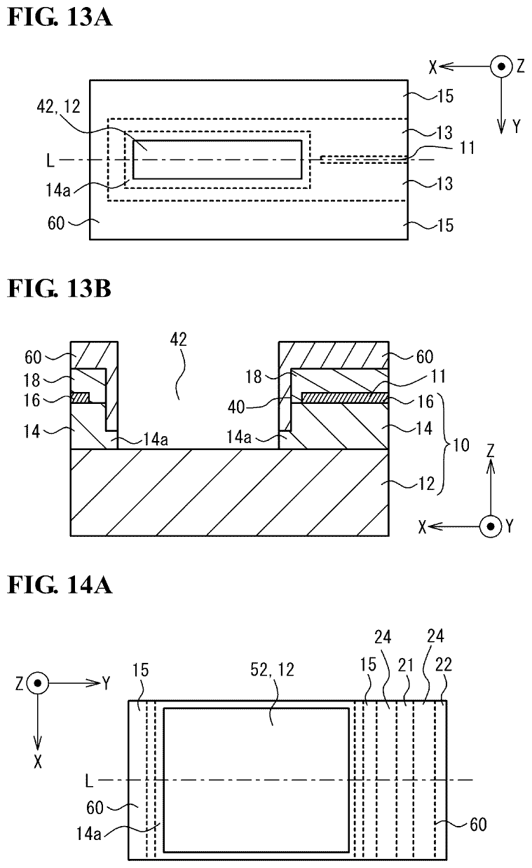

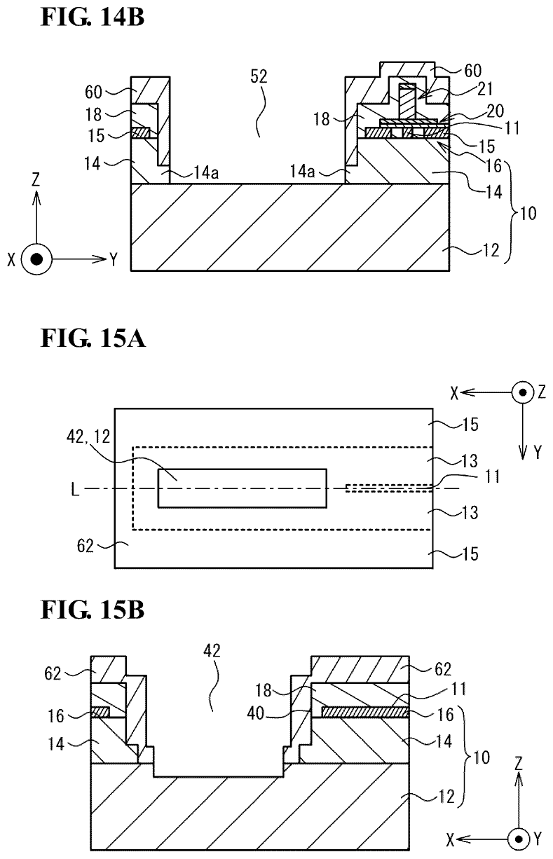

The heat dissipation structure 50 and the emitting end face 40 are formed (step S22). As shown in FIGS. 13A to 14B, etching is performed simultaneously at a position facing the tip end of the waveguide 11 and at a position spaced apart from the waveguide 11 (step S30 in FIG. 5). The insulating film 18 and the box layer 14 are etched. The substrate 12 is exposed in the recessed portion 42 and the recessed portion 52.

Specifically, etching is performed twice. Applying a resist and photolithography is performed, and the waveguide 11 and the semiconductor element 20 are covered with the resist (not shown). For example, dry etching is performed to a depth of 2.5 μm. At the point in time after the first etching, the box layer 14 remains in the recessed portion 42 and the recessed portion 52.

After the resist is removed, another resist 60 is provided on the insulating film 18. The resist 60 is patterned by photolithography. As shown in FIGS. 13A and 13B, the resist 60 covers the waveguide 11. As shown in FIGS. 14A and 14B, the resist 60 covers the semiconductor element 20. Dry etching is performed to remove the box layer 14 remaining in the recessed portion 42 and the recessed portion 52. An example of the etching conditions is shown below. Both the first and second etchings are performed under these conditions.
Gas: tetrafluoromethane (CF₄)
Antenna power: 100 W
Bias power: 50 W
Pressures: 1.0 Pa
Time: 25 minutes

The substrate 12 is exposed in the recessed portion 42 and the recessed portion 52 by the second etching. As shown in FIGS. 13A and 13B, the emitting end face 40 is formed at a position of the insulating film 18 and the box layer 14 facing the tip end of the waveguide 11. A portion 14a of the box layer 14 covered with the resist 60 remains without being etched. After the etching, the resist 60 is removed.

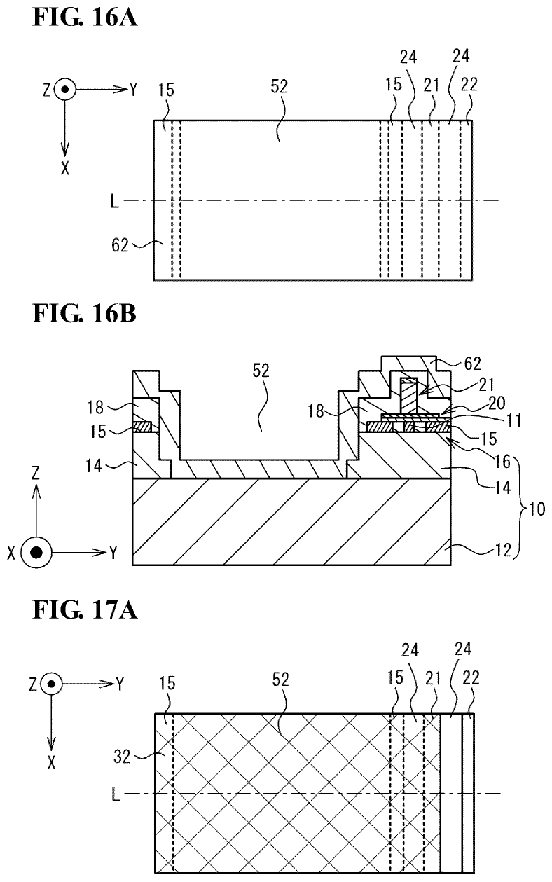

As shown in FIGS. 15A to 16B, a resist 62 is provided on the substrate 10 and the insulating film 18. As shown in FIGS. 16A and 16B, the resist 62 covers the semiconductor element 20 and the inside of the recessed portion 52. As shown in FIGS. 15A and 15B, the resist 62 covers the waveguide 11. The portion of the substrate 12 exposed from the recessed portion 42 is not covered with the resist 62. Dry etching is performed on a portion of the substrate 12 exposed from the resist 62 (step S32). In the recessed portion 42, the substrate 12 is etched to a depth of, for example, about 1 μm. After the etching, the resist 62 is removed.

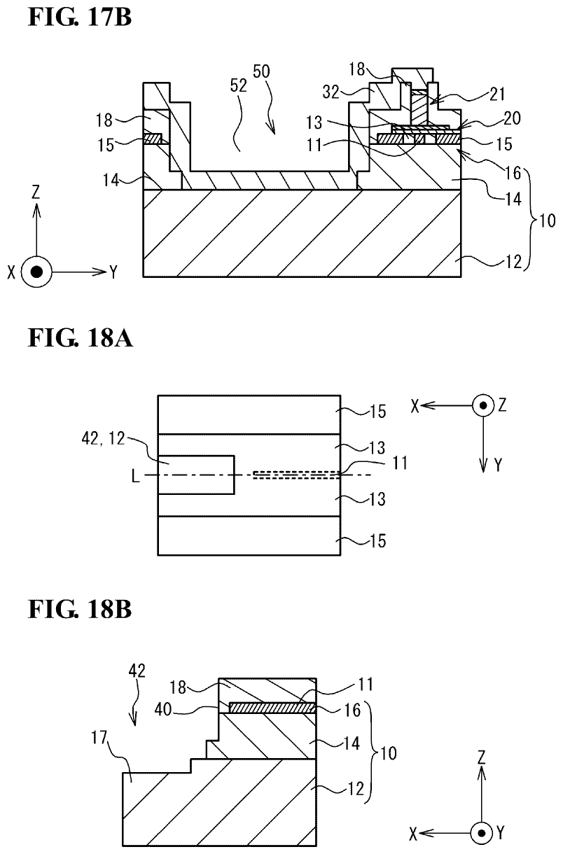

As shown in FIGS. 17A and 17B, an opening is provided in a portion of the insulating film 18 above the mesa 21. The electrode 32 is formed by vacuum deposition and lift-off (step S34). The electrode 32 is formed in a portion indicated by a diagonal line in FIG. 17A. The electrode 32 extends from the mesa 21 to the recessed portion 52, and extends from the semiconductor element 20 to the insulating film 18 opposite to the recessed portion 52. The heat dissipation structure 50 is formed. The electrode 30, shown in FIG. 1, is also provided.

As shown in FIGS. 18A and 18B, dicing is performed to separate the wafer into chips (step S24 in FIG. 4). The dicing may be laser dicing or dicing using a blade. The portion of the substrate 12 located within the recessed portion 42 is cut off and remains as the protruding portion 17. The emitting end face 40 is not in contact with a cutting method (laser, blade, etc.) of the dicing. The semiconductor light element 100 is formed by the above steps.

### Comparative Example

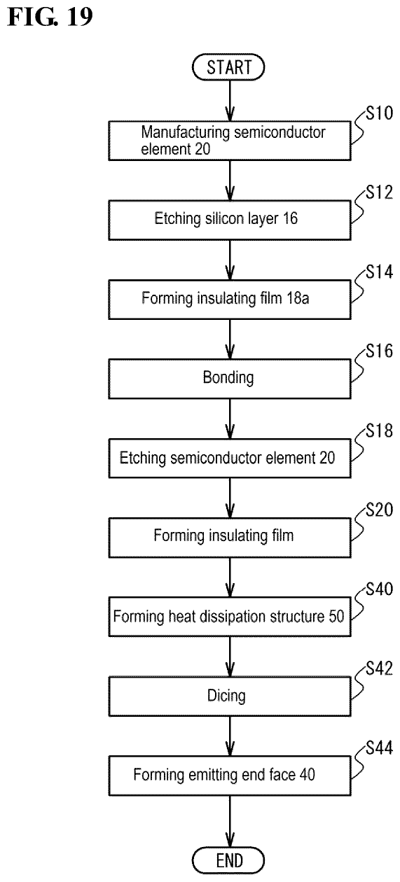

FIG. 19 is a flow chart illustrating the manufacturing steps in a comparative example. The steps from the step S10 to the step S20 are the same as those in the example of FIG. 4. The heat dissipation structure 50 is formed (step S40). The insulating film 18 and the box layer 14 are etched at a position spaced apart from the waveguide 11. The electrode 30 and the electrode 32 are provided. Etching is not performed at a position facing the tip end of the waveguide 11. After the heat dissipation structure 50 is provided, dicing is performed (step S42). The diced surface is polished to form an emitting end face (step S44).

In the comparative example, the step of forming the emitting end face and the step of forming the heat dissipation structure 50 are performed separately. Since the diced surface is rough, a flat emitting end face is formed by polishing. Since the steps are complicated and each chip is polished, the lead time becomes longer. In the polishing step, the chip is polished by, for example, about 100 μm. In the dicing step, a chip including a portion to be polished is formed. Thus, the number of chips that can be manufactured from a wafer is reduced.

According to the embodiment, the etching in the step of forming the emitting end face 40 and the etching in the step of forming the heat dissipation structure 50 are performed simultaneously. Since the steps are simplified, the lead time can be shortened.

Specifically, as shown in FIGS. 13A to 14B, the insulating film 18 and the box layer 14 are etched at a position facing the tip end of the waveguide 11 and at a position spaced apart from the waveguide 11. The emitting end face 40 is formed by dry etching, and thus has a flat surface. Since the emitting end face 40 does not need to be polished, the lead time can be shortened. The length D3 of the recessed portion 42 is, for example, 30 μm, which is smaller than the length of the portion to be polished. The number of chips manufactured from the wafer increases.

The emitting end face 40 and the heat dissipation structure 50 are formed on the plurality of chips by simultaneously etching the plurality of chips in the wafer. The lead time can be shortened.

The etching is dry etching using a gas containing carbon such as CF₄. Since the gas generates a deposit, side etching is less likely to occur. The emitting end face 40 becomes flat and approaches a vertical. As shown in FIG. 3, the coupling efficiency is increased.

The emitting end face 40 has the angle θ of 80 degrees to 90 degrees with respect to the X-axis direction, for example. As shown in FIG. 3, the coupling efficiency increases as the emitting end face 40 approaches 90 degrees, and for example, the coupling efficiency is 3 dB or more.

As shown in FIG. 2A, the emitting end face 40 is the end face of the insulating film 18 and the box layer 14. The insulating film 18 and the box layer 14 are located between the waveguide 11 and the emitting end face 40. The difference in the refractive indices between the waveguide 11 of Si, and the insulating film 18 of SiO₂ and the box layer 14 is smaller than the difference in the refractive indices between the waveguide 11 and air. The refractive index gradually changes between the waveguide 11 and air. The insulating film 18 covers the tip end of the waveguide 11 and functions as an antireflection film. The loss of light is reduced.

The substrate 10 is an SOI substrate. The box layer 14 and the insulating film 18 are formed of SiO₂. Since the same material is etched, the etching rate and the like can be easily controlled, and the recessed portion 42 and the recessed portion 52 having a desired shape can be formed. The emitting end face 40 can be flat and nearly vertical. The substrate 12 and the silicon layer 16 are formed of Si. The waveguide 11 of the silicon layer 16 is also formed of Si. The waveguide 11 of Si is surrounded by the box layer 14 and the insulating film 18 of SiO₂. Since the insulating film 18 functions as a cladding layer, light is distributed in the waveguide 11, and the loss of light is reduced.

As shown in FIGS. 13A to 14B, etching is performed until the substrate 12 is exposed, and the recessed portion 42 and the recessed portion 52 are formed. Etching may be performed at two positions simultaneously and to the same depth. Thus, the lead time can be shortened.

As shown in FIGS. 15A and 15B, the substrate 12 in the recessed portion 42 is etched. The substrate 12 is farther from the waveguide 11 in the Z-axis direction. The light is less likely to hit the substrate 12, and the loss is reduced.

As shown in FIGS. 18A and 18B, after the emitting end face 40 and the heat dissipation structure are formed, the substrate 10 is diced. A portion of the substrate 12 in the recessed portion 42 remains as the protruding portion 17. When the protruding portion 17 is long, light may hit the protruding portion 17. The length of the protruding portion 17 is, for example, 5 μm or less, and thus light is emitted to the outside without being blocked by the protruding portion 17. The loss of light is reduced.

As shown in FIGS. 17A and 17B, after etching, the electrode 32 is provided to form the heat dissipation structure 50. The electrode 32 extends from the mesa 21 of the semiconductor element 20 to the substrate 12 exposed in the recessed portion 52. Heat generated in the semiconductor element 20 is transmitted to the substrate 12 through the electrode 32 and is then dissipated. The temperature is unlikely to rise and the performance is unlikely to decrease.

Although the embodiments of the present disclosure have been described in detail, the present disclosure is not limited to the specific embodiments, and various modifications and changes can be made within the scope of the gist of the present disclosure described in the claims.

What is claimed is:

1. A method of manufacturing a semiconductor light element including a substrate having a first layer, a second layer, and a third layer stacked in this order, and a semiconductor element having an optical gain,
wherein the third layer is provided with a waveguide,
wherein the method includes:
bonding the semiconductor element to the waveguide in the third layer;
providing an insulating film covering the substrate and the semiconductor element bonded to the waveguide;
forming an emitting end face facing a tip end of the waveguide; and
forming a heat dissipation structure provided at a position spaced apart from the waveguide,
wherein the forming the emitting end face includes etching a portion of the second layer and the insulating film, the portion facing the tip end of the waveguide,
wherein the forming the heat dissipation structure includes etching a portion of the second layer and the insulating film, the portion being spaced apart from the waveguide, and providing a metal layer extending between the portion etched in the etching and the semiconductor element, and
wherein the etching in the forming the emitting end face and the etching in the forming the heat dissipation structure are performed simultaneously.

2. The method of manufacturing a semiconductor light element according to claim 1,
wherein the etching in the forming the emitting end face and the etching in the forming the heat dissipation structure include performing a dry etching using a gas containing carbon.

3. The method of manufacturing a semiconductor light element according to claim 1,
wherein the emitting end face has an angle of 80 degrees to 90 degrees with respect to an extending direction of the waveguide.

4. The method of manufacturing a semiconductor light element according to claim 1,
wherein the emitting end face is formed of end faces of the insulating film and the second layer.

5. The method of manufacturing a semiconductor light element according to claim 1,
wherein the second layer and the insulating film are formed of silicon oxide, and
wherein the first layer and the third layer are formed of silicon.

6. The method of manufacturing a semiconductor light element according to claim 1,
wherein the etching in the forming the emitting end face and the etching in the forming the heat dissipation structure include etching the second layer and the insulating film until the first layer is exposed.

7. The method of manufacturing a semiconductor light element according to claim 6, further comprising:
etching the first layer exposed at a position facing the tip end of the waveguide after the forming of the emitting end face.

8. The method of manufacturing a semiconductor light element according to claim 6, further comprising:
dicing the first layer after the forming the heat dissipation structure and the forming the emitting end face,
wherein the dicing includes dicing a portion of the first layer outside the emitting end face.

9. The method of manufacturing a semiconductor light element according to claim 1,
wherein the metal layer is an electrode and is electrically connected to the semiconductor element.

10. A semiconductor light element comprising:
a substrate including a first layer, a second layer, and a third layer that are stacked in this order;
a semiconductor element having an optical gain; and
a heat dissipation structure configured to dissipate heat from the semiconductor element,
wherein the third layer is provided with a waveguide,
wherein the semiconductor element is bonded to the waveguide in the third layer,
wherein the substrate has an emitting end face to emit light propagating through the waveguide, and
wherein the first layer has a protruding portion facing toward an extending direction of the waveguide at the emitting end face.
